(19) United States
(12) Patent Application Publication
(10) Pub. No.: US 2003/0160313 A1
(43) Pub. Date: Aug. 28, 2003

(54) Semiconductor device

(75) Inventors: Motomi Ichihashi, Tokyo (JP); Yukio Yasuda, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, Tokyo (JP)

(21) Appl. No.: 10/237,688

(22) Filed: Sep. 10, 2002

(30) Foreign Application Priority Data
Feb. 28, 2002 (JP) 2002-53481

(51) Int. Cl. H01L 23/02

(52) U.S. Cl. 257/678

(57) ABSTRACT

A semiconductor device includes a resin molded semiconductor element having a resin package and a plurality of connection leads disposed at one side of the resin package. An electromagnetic shielding member is disposed externally on the resin molded semiconductor element. The electromagnetic shielding member is made of a conductive or semi-conductive material and is in the form of an open-ended tubular covering. The resin package is inserted into the tubular covering through an opening thereof to enable the tubular covering to wrap the resin package with the connection leads extending outwardly through the opening.

### BACKGROUND OF THE INVENTION

1. Field of the Invention

The present invention relates generally to a semiconductor device that is used in practice in the vicinity of one or more high voltage generating component parts and, in particular but not exclusively, to the semiconductor device of the kind wherein an electromagnetic shielding member is utilized to increase the output characteristics and also to avoid any possible erroneous operation.

2. Description of the Related Art

With the progress of compactization and integration of electric appliances, the necessity has often occurred of one or more semiconductor devices to be disposed in the vicinity of high voltage generating component parts. In such environment where the semiconductor device is disposed in the vicinity of the high voltage generating component parts, it is well recognized that the semiconductor device may risk an abnormality in operation under the influence of an electric field developed by the adjacent high voltage generating component parts. Until this time, to avoid this risk, the semiconductor device has been positioned a distance apart from the high voltage generating component parts or a shielding plate has been disposed between the semiconductor device and the high voltage generating component parts. Where further compactization is desired, it is necessary to provide an addition of the shielding effect to the semiconductor device itself.

FIG. 1 illustrates a conventional semiconductor device. As shown therein, a lead frame and a semiconductor chip (not shown) for signal processing are encapsulated by a molded resin 50 with external connector leads 52 extending outwardly from the molded resin 50. In practice, however, a single lead frame is used for carrying a plurality of semiconductor chips through corresponding tie bars during the manufacture of semiconductor devices and, therefore, after the molding operation the tie bars are cut to separate the semiconductor chips from the lead frame, thereby providing the separate semiconductor devices. As a matter of practice, each of the separate semiconductor devices has remnant pieces 54 of the associated tie bars, which may or may not eventually define respective terminal leads of the resultant semiconductor device.

Since the semiconductor device so obtained is not of a structure utilizing any shielding member, the semiconductor device when disposed in the vicinity of high voltage generating component parts is susceptible to the electric field developed by the high voltage generating component parts, which eventually results in an erroneous operation.

Various semiconductor devices having a shield member have hitherto been proposed and, for example, Japanese Laid-open Patent Publication No. 11-4007 discloses a semiconductor signal receiver that is utilized in the environment rich of a strong electric field. This known semiconductor device is of a structure wherein a conductive resin molded component is deposited over a non-conductive resin molded component partly or generally wholly with the conductive resin molded component adapted to be connected with a grounding pin.

Japanese Laid-open Patent Publication No. 6-112362 discloses a resin sealed package for a high frequency element, which package has upper and side faces covered with a conductive shielding plate to avoid emission of unnecessary signals from the upper and side faces of the resin sealed package.

Japanese Laid-open Utility Model Publication No. 56-155454 discloses a semiconductor device wherein a plastic resin sealed package is covered with a metallic covering that is electrically connected with a grounded metallic foil deposited on a printed circuit board.

Similar techniques are disclosed in various patent literature including, inter alia, Japanese Laid-open Patent Publications No. 56-60098, No. 57-31860, No. 59-4199, No. 2-5555, No. 2-105557, No. 4-94560, No. 4-180659, No. 9-223761, No. 11-26646 and so on.

It has, however, been found that all of those publications are far from disclosure of the shielding member of a simplified structure, the number of component parts or the number of assembling steps being reduced, or the capability of use of shielding means in the existing semiconductor device having component parts already mounted. Therefore, the need is recognized to provide an improved semiconductor device robust to the electric field in the environment in which it is used.

### SUMMARY OF THE INVENTION

Accordingly, the present invention has been devised to substantially eliminate the inconveniences discussed above and is intended to provide an improved semiconductor device wherein an electromagnetic shielding member of a simplified structure is employed to increase the output characteristic to thereby avoid any possible erroneous operation and, hence, to thereby increase the durability.

In accomplishing the above and other objectives, the present invention in one aspect thereof provides a semiconductor device including a resin molded semiconductor element including a resin package having first and second sides opposite to each other, and an electromagnetic shielding member disposed externally on the resin molded semiconductor element. The electromagnetic shielding member is made of a conductive or semi-conductive material. While the semiconductor element has a plurality of connection leads disposed at the first side of the resin package, the shielding member in the form of an open-ended tubular covering having an opening accommodates therein the resin package inserted thereinto through the opening to enable the tubular covering to wrap the resin package with the connection leads extending outwardly through the opening.

According to the present invention, the use of the electromagnetic shielding member in the form of the open-ended tubular covering is effective to provide the semiconductor device having a high electromagnetic shielding effect with a simplified structure. Also, the open-ended tubular covering can advantageously be employed in any of the existing semiconductor elements or packages that are required or desired to have an electromagnetic shielding function.

The tubular covering used for the electromagnetic shielding member preferably has a volume resistivity within the range of 1×10⁵ to 1×10¹² Ωcm. The use of the tubular covering having the specific volume resistivity is effective not only to provide the predetermined shielding effect, but also to avoid any possible problem associated with leakage between or among terminals of the semiconductor device.

The semiconductor element may have a tie bar remnant piece left in the second side of the resin package. In such case, a portion of the tie bar remnant piece that is exposed to the outside from the second side is preferably held in contact with the tubular covering to apply a fixed potential to the tubular covering, so that the shielding effect can advantageously be increased with an extremely simplified structure.

Also, the tubular covering may be formed with a recess or through-hole, so that the tie bar remnant piece can be contacted with the tubular covering through the recess or through-hole. This ensures that the tubular covering can be assuredly connected with the fixed potential, thereby increasing the reliability of the electromagnetic shielding function.

In another aspect of the present invention, the electromagnetic shielding member is employed in the form of an open-ended tubular elastic covering having an opening and also having a plurality of through-holes defined in a bottom area thereof for each of the connection leads. The resin package is inserted into the tubular elastic covering through the opening thereof to enable the tubular covering to wrap the resin package with the connection leads extending outwardly through the respective through-holes. The connection leads extending through the respective through-holes are selectively contacted with the tubular elastic covering to enable a fixed potential to be applied to the tubular elastic covering.

With this arrangement, not only can the fixed potential be stably applied to the tubular covering with the simplified structure, but it is also possible to avoid any possible separation of the tubular covering from the resin package. Accordingly, the highly reliable semiconductor device can be provided at a low cost. Also, external stresses applied on the semiconductor element can be reduced to thereby increase the lifetime of the resultant semiconductor device.

In a further aspect of the present invention, a semiconductor device includes a semiconductor element and a resin package molded on the semiconductor element. The resin package is made of a semi-insulating or conductive molding resin having a volume resistivity within the range of 1×10⁵ to 1×10¹² Ωcm to thereby enable the molding resin to be used as an electromagnetic shielding member. The use of the tubular covering having the specific volume resistivity is effective not only to provide the predetermined shielding effect with a simplified structure, but also to avoid any possible problem associated with leakage between or among terminals of the semiconductor device.

The resin package may include an insulating molding resin selectively formed on the semiconductor element, and the electromagnetic shielding member is formed over the insulating molding resin. Even with this feature, it is possible to provide a semiconductor device having a high electromagnetic shielding effect.

### BRIEF DESCRIPTION OF THE DRAWINGS

The above and other objectives and features of the present invention will become more apparent from the following description of preferred embodiments thereof with reference to the accompanying drawings, throughout which like parts are designated by like reference numerals, and wherein:

FIG. 1 is a schematic side view of a conventional semiconductor device;

FIG. 2 is a vertical sectional view of a resin molded semiconductor device according to a first embodiment of the present invention;

FIG. 3 is a vertical sectional view of a resin molded semiconductor device according to a second embodiment of the present invention;

FIG. 4 is a vertical sectional view of a resin molded semiconductor device according to a third embodiment of the present invention; and

FIG. 5 is a vertical sectional view of a resin molded semiconductor device according to a fourth embodiment of the present invention.

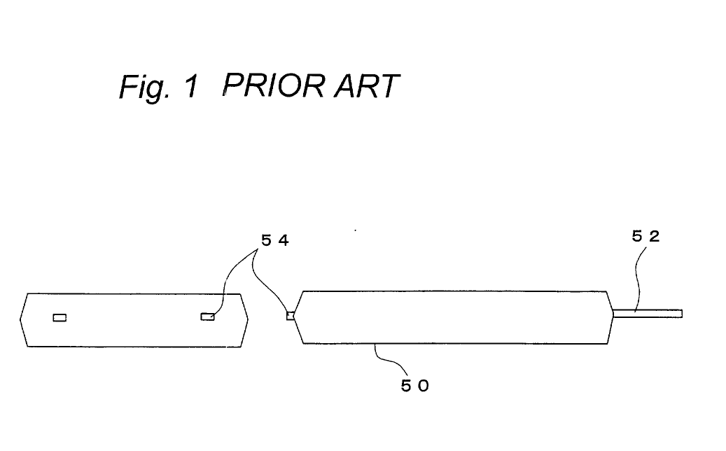

### DETAILED DESCRIPTION OF THE PREFERRED EMBODIMENTS

This application is based on an application No. 2002-53481 filed Feb. 28, 2002 in Japan, the content of which is herein expressly incorporated by reference in its entirety.

(Embodiment 1)

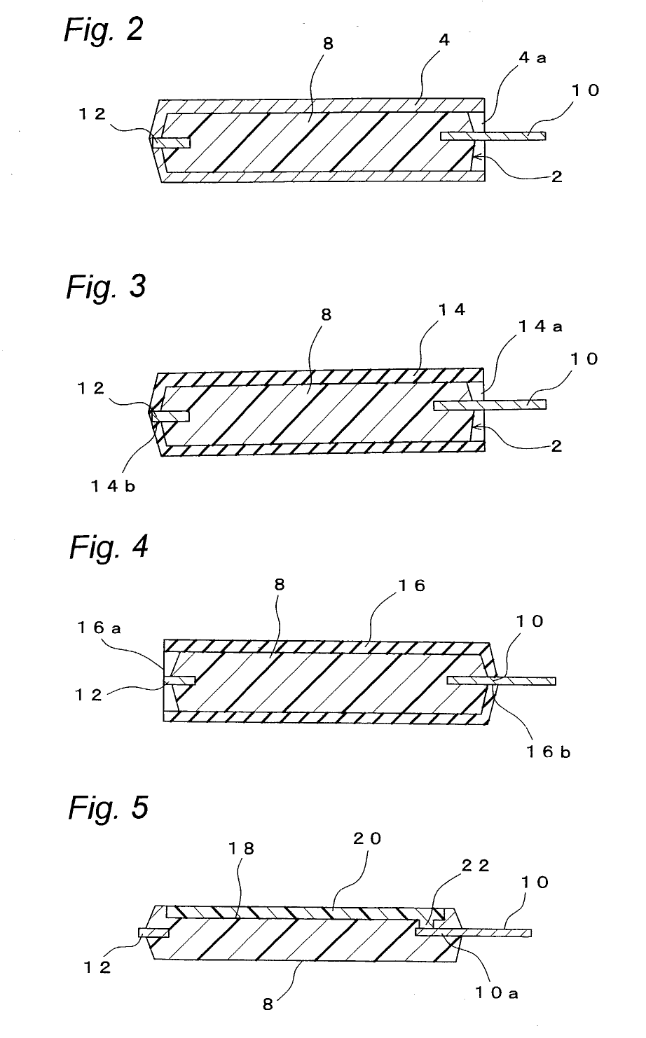

Referring first to FIG. 2, there is shown a resin molded semiconductor device according to a first embodiment of the present invention in a longitudinal sectional representation. This semiconductor device includes a resin-molded semiconductor element 2 of a generally rectangular configuration covered in its entirety with an electromagnetic shielding member. The electromagnetic shielding member employed in the practice of this embodiment of the present invention is in the form of an open ended tubular covering 4 having an opening 4a at one end thereof. The semiconductor element 2 is accommodated within the tubular covering 4, having been inserted thereinto through the opening 4a. This tubular covering 4 may be made of a conductive or semi-conductive material such as a metal or the like.

The semiconductor element 2 shown therein is in the form of a resin package 8 enclosing inner leads of a lead frame and a semiconductor chip (not shown) for signal processing mounted on the lead frame and sealed by an electrically insulating molding resin. The resin package 8 and, hence, the semiconductor element 2 has a plurality of connection leads 10 extending outwardly from one side thereof for electrical connection with an external circuit.

As hereinbefore described, the single lead frame carries a plurality of semiconductor chips and, after the packages 8 have been completed by resin molding, the packages 8 are cut to separate the packages 8 from the lead frame to thereby provide the separate semiconductor elements 2. Tie bars connecting between the resin packages 8 and the lead frame when being cut to separate the packages 8 from the lead frame leave remnant pieces 12 that remain embedded in the individual resin package 8 at one side thereof opposite to the side from which the connection leads 10 extend outwardly.

When completing the resin molded semiconductor device using the resin package 8 of the structure described above, the resin package 8 is first positioned with the opening 4a of the tubular covering 4 confronting the side of the package 8 where the tie bar remnant pieces 12 are situated, followed by insertion of the package 8 into the tubular covering 4 so as to wrap the package 8 with the connection leads 10 extending outwardly through the opening 4a of the tubular covering 4.

As such, since according to the present invention the semiconductor element 2 is covered with the conductive or semi-conductive covering 4, the covering 4 provides a shielding effect with which even when the semiconductor device is disposed in the vicinity of one or more high voltage generating component parts, the semiconductor device can be protected from the electric field developed by the high voltage generating component parts. Accordingly, not only is it possible to improve the output characteristics of the semiconductor device, but it is also possible to avoid any possible erroneous operation of the semiconductor device.

A side face of the resin package 8 where the connection leads 10 appear cannot be covered with the covering 4, or otherwise the connection leads 10 may be electrically short-circuited by a portion of the covering 4. However, the covering 4 may be connected with one of the connection leads 10 that is used as a grounding terminal, to thereby increase the shielding effect.

Also, when the tie bar remnant pieces 12 are electrically connected at an inner end with a fixed potential area of the embedded semiconductor chip within the package 8 and at an outer end with the covering 4, the shielding effect can be further enhanced.

While in the foregoing embodiment the resin package 8 has been covered with the tubular covering 4, in place of the tubular covering 4 a surface area of the resin package 8 may be electroplated with a conductive material. Even with the electroplating formed on the surface area of the resin package 8, a shielding effect similar to that afforded by the previously described embodiment can be obtained. This shielding effect may be enhanced if when the resin package 8 is electroplated, the resultant electroplated layer is held in contact with the tie bar remnant pieces 12.

(Embodiment 2)

FIG. 3 illustrates a resin molded semiconductor device according to a second embodiment of the present invention. In this embodiment, in place of the conductive tubular covering 4 used for the shielding member in the previously described embodiment, a semi-conductive elastic covering 14 made of, for example, a semi-conductive rubber material or the like is employed for the shielding member. This elastic covering 14 is in a tubular or bag form and encloses the resin package 8 therein except for the opening 14a thereof permitting that side of the resin package 8 to be exposed to the outside together with the connection leads 10.

According to this second embodiment, since the elastic covering 14 has a low hardness, enclosure of the semiconductor element 2 provides the resultant semiconductor device with an external stress cushioning effect and, therefore, increase in durability of the semiconductor device can be expected.

The elastic covering 14 has a range of volume resistivity, the upper and lower limits of which are determined in dependence on the shielding effect and a permissible leak from terminals, and preferably a volume resistivity within the range of 1×10⁵ to 1×10¹² Ωcm. In the case of connection with a specific terminal of the connection leads 10 or with the tie bar remnant pieces 12, the volume resistivity of the elastic covering 14 may not be bound by the lower limit thereof and a conductive rubber having a volume resistivity as extremely low as 0 Ω may be employed for the elastic covering 14 to allow the latter to exhibit an increased shielding effect.

Also, since the tie bar remnant pieces 12 connected with the fixed potential area within the semiconductor element and the elastic covering 14 are assuredly connected with each other, a portion of the elastic covering 14 where the elastic covering 14 is brought into contact with the tie bar remnant pieces 12 (a portion of the elastic covering 14 remote from the opening 14a of the covering 14) may be formed with recesses or through-holes 14b. In such case, when the semiconductor device is to be completed, the tie bar remnant pieces 12 may be inserted into the associated recesses or through-holes 14b while being electrically connected with the fixed potential area internally within the package 8, no insulation is needed and, accordingly, the use of the conductive rubber having as extremely low a volume resistivity as 0 Ω as material for the elastic covering 14 will result in further increase of the shielding effect.

It is to be noted that in place of the use of the tubular covering 14, the shielding member may be provided externally on the resin package 8 and, hence, the semiconductor element 2 by dipping or spray-coating it with a conductive or semi-conductive material to thereby form a shielding coating over the surface area of the semiconductor element 2. In this case, an enhanced shielding effect can be obtained if the tie bar remnant pieces 12, connected with the fixed potential area, or the specific connection lead 10 that is grounded is also covered by the dipped or sprayed coating.

In addition, as a modified form of the structure shown in FIG. 3, the elastic covering 14 may not be always necessary. More specifically, instead of the elastic covering 14, a molding resin to be used for sealing the semiconductor chip for signal processing may be added with impurities such as carbon black that is effective to lower the insulating property of the molding resin, to thereby provide a semi-insulating or conductive molding resin. After the preparation of this semi-insulating or conductive molding resin, the latter is conditioned or otherwise adjusted to have a volume resistivity within the range of 1×10⁵ to 1×10¹² Ωcm as is the case with the elastic covering 14, so that the shielding effect similar to that afforded by the structure shown in FIG. 3 can be obtained.

As a further modification, the molding resin referred to above may be employed in the form of an electrically insulating resin similar to that employed in the first or second embodiment referred to above or in the third embodiment of the present invention as will subsequently be described, in which case after the semiconductor chip has been sealed with this molding resin, the resultant semiconductor chip is to be sealed with the semi-insulating or conductive resin having its insulating property lowered in the manner described above. It is to be noted that when the semiconductor chip is to be sealed with the first used molding resin, it may be selectively molded at regions where insulation is required.

In either of those modifications, in the case of connection with the specific connection lead 10, that is to be grounded, or with the tie bar remnant pieces 12, the use of the conductive resin of a value extremely close to 0 Ω is effective to enhance the shielding effect.

(Embodiment 3)

A resin molded semiconductor device according to a third embodiment of the present invention is shown in FIG. 4. While in the second embodiment shown in FIG. 3 the opening 14a of the elastic covering 14 is positioned in face-to-face relation with the side of the semiconductor element 2 from which the connection leads 10 extend outwardly, in the embodiment shown in FIG. 4 a semi-conductive elastic covering 16 similar in composition to that of the elastic covering 14 encloses the resin package 8 with its opening 16a positioned in face-to-face relation with the side of the semiconductor element 2 where the tie bar remnant pieces 12 are situated. On the other hand, a bottom region of the elastic covering 16 opposite to the opening 16a is formed with through-holes 16b each used for one of the connection leads 10 to extend outwardly of the elastic covering 16 therethrough.

When completing the resin molded semiconductor device, the resin package 8 is first positioned with the opening 16a of the covering 16 confronting the side of the package 8 where the connection leads 10 are situated, followed by insertion of the package 8 into the covering 16 until the connection leads 10 extend outwardly through the through-holes 16b while wrapping the package 8 with the side of the package 8 remote from the through-holes 16b confronting the tie bar remnant pieces 12. The connection leads 10 extending outwardly of the covering 16 through the respective through-holes 16b are selectively contacted with the elastic covering 16 so that a fixed potential can be applied thereto.

It may occur that a peripheral lip region defining each through-hole 16b in the bottom region of the elastic covering 16 may be oversized to avoid contact of the elastic covering 16 with the respective connection lead 10 where any abnormality in characteristics otherwise brought about by leakage is desired to be alleviated. However, considering that the conductive rubber having as extremely low a volume resistivity as 0 Ω can be employed as material for the elastic covering 16, an enhanced shielding effect can be appreciated.

(Embodiment 4)

FIG. 5 illustrates a resin molded semiconductor device according to a fourth embodiment of the present invention. In this embodiment, an outer surface area of the resin package 8 or a portion of the resin package 8 that is susceptible to an electric field is formed with a recess 18, and a semi-conductive or conductive resin 20 is filled in the recess 18 by the use of any known potting technique and is subsequently allowed to cure.

Also, the resin package 8 has a through-hole or through-holes 22 defined therein for communicating between the recess 18 and specific inner ends 10a of the connection leads 10, and when such inner ends 10a are connected with a fixed potential area and with the semi-conductive or conductive resin 20 through a portion of the resin 20 filled in the through-holes 22, an enhanced shielding effect can be obtained.

Although the present invention has been fully described by way of examples with reference to the accompanying drawings, it is to be noted here that various changes and modifications will be apparent to those skilled in the art. Therefore, unless such changes and modifications otherwise depart from the spirit and scope of the present invention, they should be construed as being included therein.

What is claimed is:

1. A semiconductor device comprising:
a resin molded semiconductor element including a resin package, said resin package having first and second sides opposite to each other, said semiconductor element having a plurality of connection leads disposed at the first side of the resin package; and
an electromagnetic shielding member disposed externally on the resin molded semiconductor element, said electromagnetic shielding member made of a conductive or semi-conductive material and being in the form of an open-ended tubular covering having an opening, said resin package being inserted into the tubular covering through the opening thereof to enable the tubular covering to wrap the resin package with the connection leads extending outwardly through the opening.

2. The semiconductor device according to claim 1, wherein the tubular covering has a volume resistivity within a range of 1×10⁵ to 1×10¹² Ωcm.

3. The semiconductor device according to claim 1, wherein the semiconductor element also has a tie bar remnant piece left in the second side of the resin package, and a portion of the tie bar remnant piece that is exposed to the outside from the second side is held in contact with the tubular covering to apply a fixed potential to the tubular covering.

4. The semiconductor device according to claim 3, wherein the tubular covering is formed with a recess or through-hole and wherein the tie bar remnant piece is contacted with the tubular covering through the recess or through-hole.

5. A semiconductor device comprising:
a resin molded semiconductor element including a resin package, said resin package having first and second sides opposite to each other, said semiconductor element having a plurality of connection leads disposed at the first side of the resin package; and
an electromagnetic shielding member disposed externally on the resin molded semiconductor element, said electromagnetic shielding member being in the form of an open-ended tubular elastic covering having an opening and also having a plurality of through-holes defined in a bottom area thereof for each of the connection leads, said resin package being inserted into the tubular elastic covering through the opening thereof to enable the tubular covering to wrap the resin package with the connection leads extending outwardly through the respective through-holes, the connection leads extending through the respective through-holes being selectively contacted with the tubular elastic covering to enable a fixed potential to be applied to the tubular elastic covering.

6. A semiconductor device comprising:
a semiconductor element; and
a resin package molded on the semiconductor element, said resin package being made of a semi-insulating or conductive molding resin, said resin package having a volume resistivity within a range of 1×10⁵ to 1×10¹² Ωcm to thereby enable the molding resin to be used as an electromagnetic shielding member.

7. The semiconductor device according to claim 6, wherein said resin package comprises an insulating molding resin selectively formed on the semiconductor element, and the electromagnetic shielding member is formed over the insulating molding resin.
